(19) United States
(12) Patent Application Publication
(10) Pub. No.: US 2025/0063830 A1
(43) Pub. Date: Feb. 20, 2025

(54) METHOD OF MANUFACTURING A SOLAR MODULE

(71) Applicant: Alpha Assembly Solutions Inc., Waterbury, CT (US)

(72) Inventors: Narahari PUJARI, Waterbury, CT (US); P M KRITHIKA, Waterbury, CT (US); Siuli SARKAR, Waterbury, CT (US)

(21) Appl. No.: 18/719,593

(22) PCT Filed: Dec. 9, 2022
(86) PCT No.: PCT/EP2022/025566

§ 371 Date: Jun. 13, 2024

(30) Foreign Application Priority Data
Dec. 16, 2021 (IN) 202111058806

(51) Int. Cl. H01L 31/05; B23K 35/36; B23K 35/362; B23K 101/38; H01L 31/18

(52) U.S. Cl. CPC H01L 31/0512; B23K 35/3613; B23K 35/362; H01L 31/18; B23K 2101/38

(57) ABSTRACT

A method of manufacturing a solar module, the method comprising: connecting a metallic interconnector to two or more solar cells; and applying a transparent cover sheet to the two or more solar cells, wherein connecting the metallic interconnector to each solar cell of the two or more solar cells comprises: providing a solar cell having a bus bar on a surface thereof; providing a metallic interconnector having solder flux on a contact surface thereof; providing solder between the bus bar and the contact surface; and reflowing the solder to connect the metallic interconnector to the bus bar, wherein the solder flux comprises a reflective additive.

The invention relates to a method of manufacturing a solar module, a method of connecting a metallic interconnector to a solar cell, a metallic interconnector for a solar cell, a solder flux, a solar module and a method of manufacturing the metallic interconnector.

In the assembly of photovoltaic (PV) modules, the interconnection of crystalline silicon (c-Si) solar cells is typically accomplished by using automated combined tabbing and stringing equipment employing soldering. The soldering makes use of a flux. Flux reacts with, and thereby removes, oxide surface layers on both the solder and the substrates. This ensures that clean metals are presented during reflow so that wetting and associated bond formation can proceed. Fluxes are typically liquid and consist of a chemical activator package, additives, a solvent system and optionally rosin or synthetic resin. Historically, the solar industry has used alcohol based flux formulations.

In order to interconnect industrial solar cells with a front grid pattern, flat solder-coated copper wires are usually soldered to 2 to 20 busbars on the front and back surface. In order to minimize the resistive power loss in the wires and minimize stress in the cells, these wires are thin and wide. However, the shading of the cells by these wires represents a significant power loss, so-called “shading loss”, in the encapsulated modules.

In order to eliminate this shading loss, researchers have previously explored cell designs whereby all contacts are either placed on or are led to the rear side of the cells. However, such cell designs are unfavourably complicated and expensive.

In an alternative approach, in “Light-Capturing Interconnect Wire For 2% Module Power Gain”, presented at the 24th European PVSEC, 23 Sep. 2009, Hamburg, Germany, by Sachs et al., there is described the formation of triangular grooves on the top surface of the ribbon and the coating of the surface with a reflective layer such as silver. The grooves are designed so that incident light is reflected up toward the glass coversheet of the module at an angle shallow enough that it undergoes total internal reflection at the glass-air interface and is reflected back down onto the solar cell. As much as 80% of the light hitting the bus bars can potentially be recaptured, and experiments with industrial solar cells are alleged to show a 2% relative gain in encapsulated cell current and power with use of this light-capturing interconnect wire as compared to the controls with standard wire. However, such an approach is expensive, and works well only for perpendicularly impinging radiation.

The present invention seeks to tackle at least some of the problems associated with the prior art or at least to provide a commercially acceptable alternative solution thereto.

The present invention provides a method of manufacturing a solar module, the method comprising:
connecting a metallic interconnector to two or more solar cells; and
applying a transparent cover sheet to the two or more solar cells,

wherein connecting the metallic interconnector to each solar cell of the two or more solar cells comprises:
providing a solar cell having a bus bar on a surface thereof;
providing a metallic interconnector having solder flux on a contact surface thereof;
providing solder between the bus bar and the contact surface; and
reflowing the solder to connect the metallic interconnector to the bus bar, wherein the solder flux comprises a reflective additive.

Each aspect or embodiment as defined herein may be combined with any other aspect(s) or embodiment(s) unless clearly indicated to the contrary. In particular, any features indicated as being preferred or advantageous may be combined with any other feature indicated as being preferred or advantageous.

The inventors have surprisingly found that the resulting solar module exhibits reduced shading loss in comparison to conventional solar modules.

Due to the presence of the reflective coating in the flux, following reflow of the solder the metallic interconnector is provided with a reflective coating on its surface. Such a reflective coating may have a reflectivity of at least 10%, more typically at least 20%, even more typically at least 30%, even more typically at least 35%, still even more typically around 40%. In use, such a reflective coating increases the scattering of light. Without being bound by theory, it is considered that after hitting the transparent cover sheet/air boundary with an angle larger than the angle of total internal reflection (ϕTIR=) 42°, about 53% of the scattered photons statistically hit the solar cell and induce a current. This may cause an increase in quantum efficiency of up to 45%. This higher quantum efficiency leads to an increased short circuit current density, and thus the optically inactive width of the ribbon is reduced.

Advantageously, in comparison to conventional solar modules, such reduced shading loss may be provided regardless of the angle of the impinging radiation. Furthermore, in comparison to conventional methods of manufacturing solar modules, the method of the present invention is simple and low cost.

The term “solar cell” or “photovoltaic cell” as used herein may encompass an electrical device that converts the energy of light directly into electricity by the photovoltaic effect, which is a physical and chemical phenomenon. The term “solar module” or “photovoltaic panel” as used herein may encompass multiple solar cells in an integrated group, all oriented in one plane. Photovoltaic modules often have a sheet of glass on the sun-facing side, allowing light to pass while protecting the semiconductor wafers.

The method comprises connecting a metallic interconnector to two or more solar cells. The term “metallic interconnector” as used herein may encompass a conductive wire or ribbon. By “metallic”, it is meant that the interconnector is formed of, or comprises, a metal or an alloy. Such a connection is an electrical connection.

The two or more solar cells are connected to each other via the metallic interconnector. Typically, the metallic interconnector comprises a first end and a second end, with one solar cell connected to the first end and another solar cell connected to the second end. Typically, the metallic connector connects the top (i.e. light-facing) surface of one solar cell with the bottom (i.e. non-light-facing surface) of another solar cell, i.e. the metallic interconnector may connect the positive surface of one solar cell to the negative surface of another solar cell.

The method comprises applying a transparent cover sheet to the two or more solar cells. Specifically, the transparent cover sheet is applied to the outer surfaces of the two or more solar cells, more specifically to the surfaces which, in use, receive the incident light, i.e. that face the sun. The transparent cover sheet may enable light to pass through to underlying the solar cells while physically protecting the solar cells.

Connecting the metallic interconnector to each solar cell of the two or more solar cells comprises providing a solar cell having a bus bar on a surface thereof. The term “bus bar” is a term in the art and, as used herein, may encompass a metallic strip or bar.

Connecting the metallic interconnector to each solar cell of the two or more solar cells comprises providing a metallic interconnector having solder flux on a contact surface thereof. The term “solder flux” is a term in the art and, as used herein may encompass a chemical cleaning agent, flowing agent, or purifying agent. Solder flux may remove oxidized metal from the surfaces to be soldered, seal out air thus preventing further oxidation, and/or improve the wetting characteristics of the liquid solder by facilitating amalgamation. The term “contact surface” as used herein may encompass a surface that is comprised of a surface to be connected to the solar cell as well as a surface that in the final solar module will face the impinging light (a “light-receiving” surface). When the metallic interconnector is in the form of a ribbon, the contact surface comprises both an upper and lower surface of the ribbon. Typically, the contact surface encompasses substantially the entire outer surface of the interconnector.

Providing solder between the bus bar and the contact surface typically involves sandwiching the solder between the bus bar and the contact surface. The solder is typically provided such that it is in contact with both the bus bar and the contact surface. The term, “solder” as used herein may encompass a fusible metal alloy used to create a permanent bond between metal work pieces. Solder is melted in order to adhere to and connect the pieces after cooling, which requires that an alloy suitable for use as a solder has a lower melting point than the pieces being joined.

The solder may be pre-applied to the contact surface. In other words, the steps of “providing a metallic interconnector having solder flux on a contact surface thereof” and “providing solder between the bus bar and the contact surface” may constitute providing a metallic interconnector having solder flux and solder on a contact surface thereof and orienting the solar cell and metallic interconnector so that the solder is situated between the contact surface and the bus bar.

The solder flux comprises a reflective additive. The term “reflective additive” as used herein may encompass a species capable of reflecting light, in particular sunlight. The reflective additive is typically a solid species suspended in the liquid components of the solder flux.

The reflective additive preferably comprises a dye and/or a pigment. Such species may provide a high level of reflectivity to the reflective coating, thereby reducing the optically inactive width of the interconnector.

The reflective additive preferably comprises a pigment. In comparison to dyes, pigments exhibit increased colour-fastness. Accordingly, any decrease in performance of the solar module over time is reduced. Furthermore, in comparison to dyes, pigments tend to be less combustible, therefore decreasing the risk of fire.

In comparison to dyes, pigments tend to be less soluble in conventional flux liquids and can exhibit low levels of dispersion. As a result, the pigment is preferably coated with one or more of a polyol, a silane, an amine and an amine salt. Such species may improve compatibility with the coating, increase dispersion, and/or reduce agglomeration during storage of the flux.

The reflective additive preferably comprises a pigment comprising one or more of iron oxide, zinc oxide, aluminum oxide, titanium dioxide (e.g. infoliated TiO₂ foam), chromium oxide, pyrelene, ferric ammonium ferrocyanide, silver (e.g. silver nanoparticles) and aluminium (e.g. aluminium paste). Such species may provide a high level of reflectance.

The reflective additive preferably comprises a pigment comprising titanium dioxide, more preferably wherein the titanium dioxide is in the form of flakes, even more preferably wherein the titanium oxide flakes are coated with alumina and/or zirconia. Such species are particularly suitable for use in the present invention and may provide a particularly high level of reflectance. Preferably these species are coated with one or more of a polyol, a silane, and amine and an amine salt for the reasons discussed above.

The pigment is preferably in the form of particles (e.g. a powder), more preferably flakes. Such forms may provide a high level of reflectance and light scattering. The particles or flakes preferably have a longest dimension of from 0.5 to 5 μm, more preferably from 1 to 2 μm. Such sizes may enable the pigment to be more easily incorporated into the flux.

The dye preferably comprises a fluorescent dye (also known as a “laser” dye). The presence of a fluorescent dye may increase the quantum efficiency of the solar module. Examples of such dyes include, but are not limited to, Rhodamine based dyes like rhodamine b, acid-52, fluorescent green, fluorescein, ATTo series dyes, Cy2, tamra, Cal fluor red 590 and perylene dyes.

The solder flux may further comprise an optical brightener. The term “optical brightener” as used herein may encompass a chemical compound that absorbs light in the ultraviolet and violet region (usually 340-370 nm) of the electromagnetic spectrum, and re-emits light in the blue region (typically 420-470 nm) by fluorescence. This may cause a “whitening” effect, and therefore increase the reflectance. Suitable optical brighteners include, for example, OB, OB-1, KCB, KSN, FP-127, KB, 4BK, DBH, ER-1, ER-2, ER-3, CXT, VBL, BBU and CBS-X.

The reflective additive is preferably white or yellow, more preferably white. Such colours provide a high level of reflectance.

The flux comprises from 0.1 to 15 wt. % reflective additive based on the total weight of the flux, preferably from 0.3 to 2 wt. % reflective additive. Such amounts may provide a high level of reflectance without compromising the other roles of the solder flux, such as removing oxidized metal from the surfaces to be soldered, sealing out air thus preventing further oxidation, and/or improving the wetting characteristics of the liquid solder.

The solder flux preferably further comprises an acrylic resin binder, preferably a methacrylic resin binder. The presence of such a binder, which is elastomeric, may provide the flux, and therefore the resulting reflective coating, with pliability. As a result, degradation in performance of the solar module as a result of, for example, PID (power induced degradation), is reduced. In addition, there may be a reduction in chipping or flaking during handling or feeding in automated Combined Tabbing and Stringing (CTS) equipment. The pliability may enable the solar module to assume an arbitrary shape, for example so that it can be wrapped over cars, airplane wings, buildings, robots and three-dimensional (3-D) displays. Moreover, the presence of such a binder may render the solder flux substantially “tack-free”, even at elevated operating temperatures. If the flux is tacky, the ribbon alignment suffers. Tacky flux creates alignment issues which in turn create a problem in peel strength. Also, tacky or powdery residue may stick to the pulleys, gripper and other machine parts causing frequent downtime and cosmetics issue. Tacky flux is also responsible for cell breakage. If flux is tacky or the residue after processing remains tacky, the robotic arm cannot pick the string properly. This might create microcracks in the assembled strings. Furthermore, the presence of such a binder may render the flux particularly compatible with conventional ethyl vinyl acetate (EVA) laminating material.

The solder flux preferably comprises from 1 to 10 wt. % acrylic resin binder, preferably from 2 to 6 wt. % acrylic resin binder. Lower levels may not provide a sufficient level of pliability and non-tackiness. Higher levels may compromise the other roles of the solder flux, such as removing oxidized metal from the surfaces to be soldered, sealing out air thus preventing further oxidation, and/or improving the wetting characteristics of the liquid solder.

The acrylic resin binder preferably comprises an acrylic polymer having carboxyl, hydroxyl, or amide groups, or a mixture of these, and preferably has a weight average molecular weight of 5,000-500,000 and a glass transition temperature of −20° C. to +125° C. Typically useful acrylic polymers contain alkyl methacrylate, alkyl acrylate, hydroxyalkyl acrylate, hydroxyalkyl methacrylate and can contain styrene, acrylic acid or methacrylic acid. Amide monomers such as methacrylamide and acrylamide can be used; glycidyl monomers such as glycidyl acrylate or glycidyl methacrylate can also be used. Isoprene based liquid rubber and like may also be used. Preferred acrylic polymers are of an alkyl methacrylate that has 1-18 carbon atoms in the alkyl group, an alkyl acrylate that has 1-18 carbon atoms in the alkyl group and a hydroxyalkyl acrylate or a hydroxyalkyl methacrylate each having 2-4 carbon atoms in the hydroxyalkyl group.

The solder flux preferably further comprises a vinyl resin binder. The presence of such a binder, which is elastomeric, may provide the flux, and therefore the resulting reflective coating, with pliability. As a result, degradation in performance of the solar module as a result of, for example, bending, is reduced. In addition, there may be a reduction in chipping or flaking during handling or feeding in automated Combined Tabbing and Stringing (CTS) equipment. The pliability may enable the solar module to assume an arbitrary shape, for example so that it can be wrapped over cars, airplane wings, buildings, robots and three-dimensional (3-D) displays. Moreover, the presence of such a binder may render the solder flux substantially “tack-free”, even at elevated operating temperatures. If the flux is tacky, the ribbon alignment suffers. Tacky flux creates alignment issues which in turn create a problem in peel strength. Also, tacky or powdery residue may stick to the pulleys, gripper and other machine parts causing frequent downtime and cosmetics issue. Tacky flux is also responsible for cell breakage. If flux is tacky or the residue after processing remains tacky, the robotic arm cannot pick the string properly. This might create microcracks in the assembled strings. Furthermore, the presence of such a binder may render the flux particularly compatible with conventional polyolefine (POE) and EVA laminating material.

The solder flux preferably comprises from 0.1 to 5 wt. % vinyl resin binder, preferably from 0.5 to 2 wt. % vinyl resin binder. Lower levels may not provide a sufficient level of pliability and non-tackiness. Higher levels may compromise the other roles of the solder flux, such as removing oxidized metal from the surfaces to be soldered, sealing out air thus preventing further oxidation, and/or improving the wetting characteristics of the liquid solder.

The solder flux preferably comprises both an acrylic resin (preferably a methacrylic resin) binder and a vinyl resin binder.

The solder flux is preferably substantially free of halogens, more preferably halogen-free. In comparison to halogen-containing solder fluxes, this may render the solder flux less aggressive to the materials forming the metallic interconnector and solar cell. This may improve the reliability of the solar module, and may enable the solar module to pass accelerated aging test IEC61215. Furthermore, halogen ions may remain on the cell and migrate causing current shorts.

The solder flux preferably further comprises an activator, more preferably an activator comprising a dicarboxylic acid, even more preferably wherein the dicarboxylic acid is selected from one or more of adipic acid, glutaric acid and succinic acid. Such species may be particularly suitable for removing oxidized metal from the surfaces to be soldered, sealing out air thus preventing further oxidation, and/or improving the wetting characteristics of the liquid solder.

The solder flux preferably comprises from 1 to 5 wt. % activator.

The solder flux preferably further comprises one or more of a resin, a rosin, a wetting agent, an antifoaming agent, a plasticiser, and a dispersing agent.

The solder flux preferably comprises an agent for wetting and dispersing the reflective additive (e.g. titanium dioxide). This moiety may help wetting and dispersing pigment and/or dye in the flux composition. Nonionic, cationic and/or amphoteric wetting and dispersing agents can be used, for example. Illustrative dispersants include, but are not limited to, polyethylene glycol and its derivatives (e.g. PEG100, PPG), low molecular weight poly acrylics and methacrylics, block copolymer with pigment affinic groups such as BYK2023, BYK2117, BYK180, structured copolymer, Zonyl FSN Fluorosurfactant (described as a perfluoroalkyl ethoxylate) available from E. I. DuPont de Nemours & Co., Inc., Fluorad FC-430 (described as a fluoroaliphatic polymeric ester) available from the Industrial Chemical Products Division of 3M, and ATSURF fluorosurfactants available from Imperial Chemical Industries. Other illustrative dispersants include, but are not limited to, alkoxysilanes (polyalkyleneoxide modified heptamethyltrisiloxane), ethers (allyloxypolyethyleneglycol methyl ether, polyoxyethylenecetyl ether), polydimethylsiloxane, polyether modified polydimethylsiloxane, polyester modified polydimethylsiloxane, hexadimethyl silane, hexadimethyldisilazane, polyoxyethylenesorbitan monooleate, water-soluble ethylene oxide adducts of an ethylene glycol base, water-soluble ethylene oxide-propylene oxide adducts of a propylene glycol base, a polycarboxylic acid (a dicarboxylic acid having at least 3 carbon atoms), a dimerized carboxylic acid, a polymerized carboxylic acid, and the like. A particularly suitable agent is BYK 2117.

Preferably, the bus bar comprises a copper, tin or silver connection pad, and reflowing the solder connects the metallic interconnector to the copper, tin or silver connection pad. The solder flux may enable particularly favourable wetting of solder to copper, tin and silver.

The metallic interconnector preferably comprises a copper or copper alloy ribbon. A copper or copper alloy ribbon may exhibit favourable levels of conductivity and may be soldered using conventional solders.

The transparent cover sheet preferably comprises glass. Glass is particularly suitable for protecting the solar cells while allowing impinging light to pass through to the solar cells. The glass is preferably textured.

The method preferably further comprises laminating the solar cells. Lamination may ensure complete sealing of the interconnected solar cells, which are perishable and sensitive to moisture. The laminating is preferably carried out using a laminating material selected from ethyl vinyl acetate (EVA) and polyolefin (POE). The solder fluxes of the present invention are compatible with such materials. The laminating preferably comprises applying the transparent cover sheet to the side to be exposed to radiations (“front sheet”) and applying a polymeric or composite layer on the opposite side (“backsheet”).

The solder flux may further comprise a black or blue pigment. The presence of the black or blue pigment may provide a desirable aesthetic affect to a metallic interconnector on which the solder flux is used. Accordingly, the interconnector may exhibit both an aesthetic appeal and high reflectivity.

Suitable black and/or blue pigments include, for example, ferric oxide blacks, carbon black, graphite, pigment black number 7, iron and chromium [III] oxide pigment (e.g. Sicopal® black L0095), and solvent black 9, 37, 32, 42, 48 and 49, preferably iron and chromium [III] oxide pigment (e.g. Sicopal® black L0095), Microlith® Black 0066 A and carbon black.

The solder flux preferably comprises an agent for wetting and dispersing the black and/or blue pigments. The agent may be the same as the agent discussed above for dispersing the reflective additive. Such an agent may be particularly beneficial when the black and/or blue pigment comprises carbon black. When the black and/or blue pigment comprises carbon black, a particularly suitable agent is BYK 2117.

In a further aspect, the present invention provides a method of manufacturing a solar module, the method comprising:
providing a first solar cell having a bus bar on a surface thereof;
providing a second solar cell having a bus bar on a surface thereof;
providing a metallic interconnector having a first end portion and a second end portion;
providing solder between the bus bar of the first solar cell and the first end portion; and
reflowing the solder to connect the first end portion to the bus bar of the first solar cell,
providing solder between the bus bar of the second solar cell and the second end portion;
reflowing the solder to connect the second end portion to the bus bar of the second solar cell, and
applying a transparent cover sheet to the solar cells,

wherein the first end portion and the second end portion are coated with solder flux, the solder flux comprising a reflective additive.

The advantages and preferable features of the first aspect of the present invention apply equally to this aspect.

The two steps of providing solder and/or the two steps of reflowing the solder may be carried out sequentially or at the same time.

In a further aspect, the present invention provides a method of connecting a metallic interconnector to a solar cell, the method comprising:
providing a solar cell having a bus bar on a surface thereof;
providing a metallic interconnector having solder flux on a contact surface thereof;
providing solder between the bus bar and the contact surface, and
reflowing the solder to connect the metallic interconnector to the bus bar, wherein the solder flux comprises a reflective additive.

The advantages and preferable features of the first aspect of the present invention apply equally to this aspect.

In a further aspect, the present invention provides a metallic interconnector for a solar cell, the metallic interconnector having solder flux on a surface thereof, the solder flux comprising a reflective additive and being substantially free of solvent.

The advantages and preferable features of the first aspect of the present invention apply equally to this aspect.

In automated tabbing and stringing machines, flux is typically applied on the ribbon or cell just before the soldering. Typically, flux is sprayed onto the cells/ribbons or the ribbon is dipped into a flux tank. The fluxing operation creates a lot of residue and may pollute machine parts. This in turn may increase the machine downtime, and contamination on parts/cells becomes almost inevitable. Moreover, operations like dip coating impart uneven fluxing and sometime spreading of flux on fingers and cell area is observed. Yellowing and cold solder joints are also common problems associated with standard PV fluxing. Compatibility between conventional EVA (ethylene vinyl acetate) encapsulants and flux residue also has been reported in the literature. Such problems may be avoided by the use of the metallic interconnector of the present invention. The use of a “pre-applied” flux free of solvent reduces the formation of residues and its associated problems. Furthermore, the costs and safety implications of handling and storing large volumes of flammable (typically alcoholic) solvents are avoided.

The metallic interconnector has solder flux on a surface thereof. The surface may be a contact surface as described above, i.e. a surface that is to be connected to a solar cell.

The flux is substantially free of solvent, typically completely free of solvent. The flux may comprise less than 2 wt. % solvent, typically less than 1 wt. % solvent, even more typically less than 0.1 wt. % solvent.

In a further aspect, the present invention provides a solder flux comprising a solid component and optionally a solvent, wherein the solid component comprises a reflective additive.

The advantages and preferable features of the first aspect of the present invention apply equally to this aspect.

In a preferred embodiment, the solder flux comprises from 85 to 95 wt. % solvent.

The solvent preferably comprises isopropyl alcohol. Isopropyl alcohol is particularly suitable to be used in the flux because it evaporates at typical soldering temperatures, thereby leaving less organic residue in the solder joint, which may adversely effect the electrical and mechanical performance of the joint.

In a preferred embodiment, the solder flux comprises, based on the total weight of the solder flux:
from 85 to 95 wt. % isopropyl alcohol solvent,
from 0.5 to 10 wt. % methacrylic resin binder,
from 0.1 to 5 wt. % vinyl resin binder,
from 1 to 5 wt. % activator,
from 0.3 to 2 wt. % reflective additive, preferably wherein the reflective additive comprises titanium dioxide, more preferably in the form of powder (e.g. flakes), and
optionally from 0.1 to 2 wt. % wetting agent.

Such a solder flux exhibits a particularly favourable combination of high reflectance, pliability, non-tackiness, non-aggressiveness and excellent wetting.

In a preferred embodiment, the solder flux is substantially free of solvent. This may avoid the disadvantages associated with solvents described above. Such a “solvent-free” solder flux may be applied using, for example, a “hot melt” process.

In a further aspect, the present invention provides a solder flux comprising a solid component and optionally a solvent, wherein the solid component comprises a black and/or blue pigment.

The advantages and preferable features of the first aspect of the present invention apply equally to this aspect.

The presence of the black or blue pigment may provide a desirable aesthetic affect to a metallic interconnector on which the solder flux is used.

Suitable black and/or blue pigments include, for example, ferric oxide blacks, carbon black, graphite, pigment black number 7, iron and chromium [III] oxide pigment (e.g. Sicopal® black L0095), and solvent black 9, 37, 32, 42, 48 and 49, preferably carbon black and iron and chromium [III] oxide pigment (e.g. Sicopal® black L0095). Iron and chromium [III] oxide pigment (e.g. Sicopal® black L0095) is particularly beneficial since although it is black it also reflects light, thereby providing a favourable combination of high reflectivity and favourable aesthetics.

In a preferred embodiment of this aspect, the solder flux comprises, based on the total weight of the solder flux:
from 85 to 95 wt. % isopropyl alcohol solvent,
from 0.5 to 10 wt. % methacrylic resin binder,
from 0.1 to 5 wt. % vinyl resin binder,
from 1 to 5 wt. % activator,
from 0.5 to 2 wt. % black pigment, wherein the black pigment comprises carbon black and/or and iron and chromium [III] oxide pigment, and
optionally from 0.1 to 2 wt. % wetting agent.

In an alternative preferred embodiment of this aspect, the solder flux is substantially free of solvent. This may avoid the disadvantages associated with solvents described above. Such a “solvent-free” solder flux may be applied using, for example, a “hot melt” process.

In a further aspect, the present invention provides a solar module manufactured according to the method described herein.

The advantages and preferable features of the first aspect of the present invention apply equally to this aspect.

In a further aspect, the present invention provides a method of manufacturing the metallic interconnector described herein, the method comprising:
providing a metallic interconnector,
providing the solvent-containing solder flux solder flux described herein,
applying the solder flux to the metallic interconnector, and
removing solvent from the solder flux by evaporation.

The solder flux may be applied by, for example, one or more of brushing, coating, spraying, spray coating, dipping and rolling. Evaporation may result from heating the solder flux, preferably to a temperature greater than the boiling point of the solvent.

In a further aspect, the present invention provides a method of manufacturing the metallic interconnector described herein, the method comprising:
providing a metallic interconnector,
providing the “solvent free” solder flux described herein,
melting the solder flux, and
applying the melted solder flux to the metallic interconnector.

The melted solder flux may be applied to the metallic interconnector using, for example, a “hot melt” process.

The invention will now be described with reference to the following non-limiting drawings, in which:

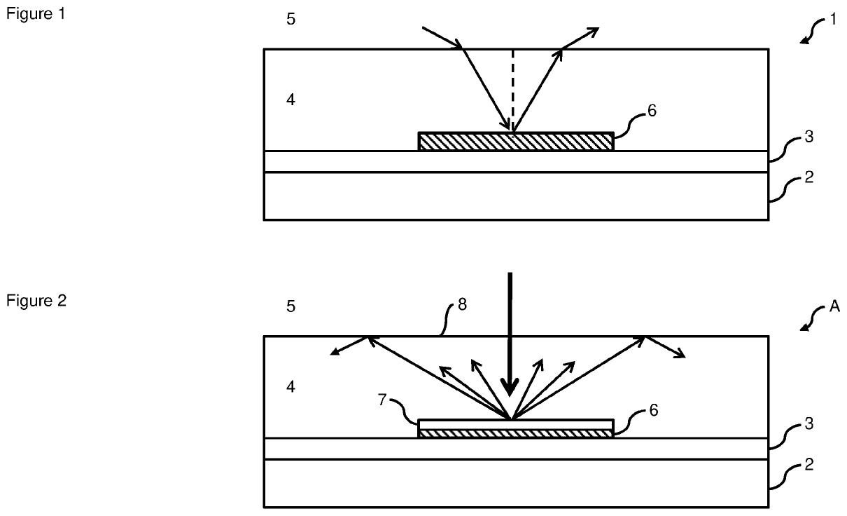

FIG. 1 is a schematic showing the path of light into and out of a conventional solar module.

FIG. 2 is a schematic showing the path of light into and out of a solar module according to the present invention.

Referring to FIG. 1 there is shown a conventional solar module (shown generally at 1). The solar cell 2 has a bus bar 3 on its surface. The side of the module for receiving light is covered with a sheet 4 made of glass having an EVA film in order to protect the solar cell 2 from the air 5. An interconnector (flat metallic ribbon) 6 acts like a mirror and reflects incoming radiation (shown by the arrows) out of the module. The area covered by the ribbons (around 3.5%) is mainly lost for photovoltaic conversion.

Referring to FIG. 2, there is shown a solar module A according to the present invention in which the ribbon 6 is coated with a reflective layer 7. After hitting the glass-air surface 8 with an angle larger than the angle of total internal reflection, a portion of the scattered photons hit the solar cell and induce a current.

The invention will now be described in relation to the following non-limiting examples.

### EXAMPLE 1

A pliable and non-tacky coating and reflective flux was prepared by blending different types of coating and binding resins, plasticizers, and organic acids such as adipic acid and succinic acid. This flux coating imparts color when coated on the metal ribbon and is reflective in nature. Inorganic pigments were dispersed in the flux. The process of making this flux is as follows: The resins were measured accurately to the amount of flux needed to be prepared and added into the clean and dry mixing container equipped with heating jacket, this mixture is along with solvent is stirred, the temperature was maintained around 60 to 70° C., until the resins are dissolved. The mixture was maintained around the mentioned temperature to avoid overheating and evaporation of the mixture. The required number of organic acids are added to this mixture and allowed to dissolve until the mixture is observed to be transparent, until all the solids are dissolved. The required amount of plasticizer is then weighed out and added to this mixture and mixed for 10 mins maintaining the temperature of the mixture at 60 to 70° C. The container was covered with a lid during this entire process. The whole mixture was set aside to cool down to the room temperature. Required amount of flux was removed from this mixture for quality control studies. The required amount of colorant for this formulation was weighed out and added into the flux formulation. When solvent was used, this mixture was sheared on a high-speed shear mixture at 7000 to 8000 rpm for about 60 to 70 mins until the colorant is completely dispersed. For hot melt process the colorant was added after solid mixture became flowable. Intermediate breaks were given to maintain the temperature of the mixture during the high shear mixing process, the temperature was maintained to be below 50° C. the resulting mixture was transferred into a container for further use or to coat metal ribbon. Any settlement seen must be redispersed before use. The dispersed flux was precoated on metal ribbons for further applications.

The flux in this example contains 5% by weight binding resins, 2% by weight organic acids, 1% by weight plasticizers and 1.5% by weight inorganic pigment. This flux was coated on the ribbons and the ribbons were subjected to reflectivity analysis, the high reflectiveness of these fluxes in turn increases the power output of the solar panel by 2.5%. Where pigment is black in color, the aesthetics of the panel improves.

Resiliency of this flux was tested by twisting the flux coated ribbon beyond 360° and bending the ribbon beyond the angle 360° and inspecting for cracks, adhesion of the coating on the ribbon. The flux coated ribbon was subjected to reflectivity analysis and possess reflectivity of 34-36%. The flux was completely tack free when coated and dried instantly. The tack was characterized by IPC-TM-650 method 2.4.44 dated March 1998.

### EXAMPLE 2

A pliable and reflective flux was prepared as described in Example 1 by combining different types of coating and binding resins, partially dimerized rosins (Poly-Pale), plasticizers, and organic acids such as adipic acid and succinic acid. The flux is reflective in nature, inorganic pigments are dispersed in flux. The flux in this example contains 1% by Ke604 and polypal rosins, 2% by weight binding resins (vinyl polymers), 2% by weight organic acids, 0.5% by weight plasticizers and 1% by weight inorganic pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 27-30%. The flux was completely tack free when coated and dried instantly. The tack was characterized by IPC-TM-650 method 2.4.44 dated March 1998.

### EXAMPLE 3

A pliable and reflective flux was prepared as described in Example 1 by combining different types of binding resins, partially dimerized rosins (Poly-Pale), plasticizers, rosins, and organic acid such as adipic and succinic acid. The flux is reflective in nature, pigment are dispersed in the flux. The in this example contains 1% Ke604 and polypal rosins, 2% by weight binding resins, 2% by weight organic acids, 0.5% by weight BYK-2023 was added. And 1.1% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 30-32%. The flux was completely tack free when coated and dried instantly. The tack was characterized by IPC-TM-650 method 2.4.44 dated March 1998.

### EXAMPLE 4

A pliable and reflective flux was prepared as described in Example 1 by combining different types of binding resins, plasticizers, organics acids such as adipic and succinic acid. The flux is reflective in nature, inorganic pigment such as Zinc Oxide are dispersed in the flux. The flux in this example contains 5% by weight binding resins, 2.2% by weight organic acids, 0.8% by weight plasticizers and 1.2% by weight inorganic acids. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 33-35%. The flux was completely tack free when coated and dried instantly. The tack was characterized by IPC-TM-650 method 2.4.44 dated March 1998.

### EXAMPLE 5

A pliable and reflective flux was prepared as described in Example 1 by combining different types of binding resins, plasticizers, organic acids such as adipic and methyl succinic acid. The flux is reflective in nature, inorganic pigment, titanium dioxide is dispersed in the flux. The flux in this example contains 5% by weight binding resins, 1.8% by weight adipic acid and 0.4% by weight methyl succinic acid, 0.8% by weight plasticizers and 1.2% by inorganic pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 33-36%. The flux was completely tack free when coated and dried instantly. The tack was characterized by IPC-TM-650 method 2.4.44 dated March 1998.

### EXAMPLE 6

A pliable and reflective flux was prepared as described in Example 1 by combining different types of binding resins, plasticizers, organic acids such as adipic acid and succinic acid. The flux is reflective in nature, pigment are dispersed in the flux. The flux in this example contains 5% by weight binding resins, 1.8% by weight adipic acid and 0.4% by weight succinic acid. 0.8% by weight plasticizers, 1.2% by weight Aluminum paste-100 microns. This flux was coated on the ribbons and the ribbons were subjected to reflectivity analysis, the high reflectiveness of these fluxes in turn increases the power output of the solar panel by 0.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 24-26%. The flux was completely tack free when coated and dried instantly. The tack was characterized by IPC-TM-650 method 2.4.44 dated March 1998.

### EXAMPLE 7

Example 1 was repeated expect that fluorescent dye, (Acid Red-52), was added to the composition. Florescent dyes absorbed light at shorter wavelength and emits at a longer wavelength thus improving the quantum efficiency and reflectivity of the coating, they produce wide angle scattering and achieve maximum total internal reflection. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 35-38%. The flux was completely tack free when coated and dried for a 5 to 6 seconds, the tack was characterized by IPC-TM-650 method 2.4.44 dated March 1998

### EXAMPLE 8

A reflective hot melt adhesive formulation was prepared as described in Example 1 by combining rosins Ke604, Versamid, organic acid such as adipic acid and palmitic acid, Ceresin wax and pigment. The flux in this example contains 22% by weight Ke604, 9% by weight Versamid, 20% by weight adipic acid, 27% by weight palmitic acid, 15% by weight Ceresin wax and 9% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 38-42%. The flux was completely tack free when coated and dried for a 5 to 6 seconds, the tack was characterized by IPC-TM-650 method 2.4.44 dated March 1998.

### EXAMPLE 9

A reflective hot melt adhesive formulation was prepared as described in Example 1 by combining rosins Ke604, Versamid, organic acid such as adipic acid and palmitic acid, Ceresin wax and pigment. The flux in this example contains 25% by weight Ke604, 10% by weight Versamid, 23% by weight adipic acid, 15% by weight palmitic acid, 20% by weight Ceresin wax and 8% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 40-50%. The flux was completely tack free when coated and dried for a 5 to 6 seconds, the tack was characterized by IPC-TM-650 method 2.4.44 dated March 1998.

### EXAMPLE 10

A reflective hot melt adhesive formulation was prepared as described in Example 1 by combining polymerized rosin dymerex, unirez-2940, organic acid such as adipic acid and palmitic acid, benzotriazole and pigment. The flux in this example contains 18% by weight dymerex, 26% by weight unirez-2940, 30% by weight adipic acid, 24% by weight palmitic acid, 1% by weight Benzotriazole and 1% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 40-50%. The flux was completely tack free when coated and dried for a 5 to 6 seconds, the tack was characterized by IPC-TM-650 method 2.4.44 dated March 1998.

### EXAMPLE 11

A reflective hot melt adhesive formulation was prepared as described in Example 1 by combining polymerized rosin dymerex, unirez-2940, organic acid such as adipic acid and palmitic acid, Benzotriazole and pigment. The flux in this example contains 20% by weight dymerex, 24% by weight unirez-2940, 25% by weight adipic acid, 27.8% by weight palmitic acid, 0.8% by weight Benzotriazole and 1.4% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 40-50%. The flux was completely tack free when coated and dried for a 5 to 6 seconds, the tack was characterized by IPC-TM-650 method 2.4.44 dated March 1998.

### EXAMPLE 12

A pliable and reflective flux was prepared as described in Example 1 by combining different types of binding resins, Rosins (Unirez-2940), plasticizers, organic acids such as adipic acid and suberic acid. The flux is reflective in nature, lab synthesized porous nanocrystalline TiO₂ infoliated foam was dispersed in this flux. The flux in this example contains 5% by weight binding resins, 1.2% by weight unirez-2940, 1.8% by weight adipic acid and 0.5% by weight succinic acid, 0.8% by weight plasticizers, 1.2% by weight infoliated TiO₂ foam was dispersed. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 14-16%. The flux was partially tacky when coated and dried for a 5 to 6 seconds, the tack was characterized by IPC-TM-650 method 2.4.44 dated March 1998.

### EXAMPLE 13

A pliable and reflective flux was prepared as described in Example 1 by combining different types of binding resins, plasticizers, organic acids such as adipic acid and succinic acid. The flux is reflective in nature, pigment are dispersed in the flux. The flux in this example contains 5% by weight binding resins, 1.8% by weight adipic acid and 0.4% by weight succinic acid. 0.8% by weight plasticizers, 2% by weight pigment (silver nano particles). This flux was coated on the ribbons and the ribbons were subjected to reflectivity analysis, the high reflectiveness of these fluxes in turn increases the power output of the solar panel.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 30-34%. The flux was completely tack free when coated and dried instantly. The tack was characterized by IPC-TM-650 method 2.4.44 dated March 1998.

### EXAMPLE 14

A pliable and reflective flux was prepared as described in Example 1 by combining different types of binding resins, KE604, partially dimerized rosins (Poly-Pale), plasticizers, organic acids such as adipic acid. The flux is reflective in nature, Pigment spacer such as Polygloss 90 and Aluminum paste 100 are dispersed in the flux. The flux in this example contains 1.6% by weight binding resins, 0.6% by weight Ke604, 0.4% by weight Polypale rosin, 2.2% by weight adipic acid, 0.6% by weight plasticizers, 1.2% by weight pigment polygloss 90 and Aluminum paste. This flux was coated on the ribbons and the ribbons were subjected to reflectivity analysis, the high reflectiveness of these fluxes in turn increases the power output of the solar panel.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 14-16%. The flux was completely tack free when coated and dried instantly. The tack was characterized by IPC-TM-650 method 2.4.44 dated March 1998.

### EXAMPLE 15

A pliable and reflective flux was prepared as described in Example 1 by combining different types of binding resins and Polymers (Polyvinyl pyrrolidine K30), plasticizers, organic acids such as adipic acid and succinic acid. The flux is reflective in nature, pigment and pigment spacer such as Polygloss 90 and Aluminum paste 100 are dispersed in the flux. The flux in this example contains 5% by weight binding resins and Polyvinyl pyrrolidine K30, 1.8% by weight adipic acid, 0.2% by weight succinic acid, 0.8% by weight plasticizers, 1.2% by weight pigment polygloss 90 and Aluminum paste. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 30-35%. The flux was completely tack free when coated and dried instantly. The tack was characterized by IPC-TM-650 method 2.4.44 dated March 1998.

### EXAMPLE 16

A pliable, reflective and UV curable flux was prepared as described in Example 1 by combining midly activated rosin anhydride adduct, polypropyleneglycol diglycidyl ether, Irgacure 184 (or ciba Darocure.R. 1173), adipic acid and succinic acid. This flux is reflective in nature, pigment like Aluminium paste-100 are dispersed into this flux. This flux in this example contains 3% by weight rosin anhydride adduct, 4% by weight polypro pyleneglycol diglycidyl ether, 1% by weight Ciba Darocure R. 1173, 1.8% by weight adipic acid, 0.4% by weight succinic acid and 1.2% by weight inorganic dye Aluminum paste-100.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 14-16%. The flux was completely tack free when coated and dried instantly. The tack was characterized by IPC-TM-650 method 2.4.44 dated March 1998.

### EXAMPLE 17

A pliable, reflective and UV curable flux was prepared as described in Example 1 by combining midly activated rosin anhydride adduct, polypropyleneglycol diglycidyl ether, Irgacure 184 (or ciba Darocure.R. 1173), adipic acid and succinic acid. This flux is reflective in nature, pigment like Aluminium paste-100 are dispersed into this flux. This flux in this example contains 6% by weight rosin anhydride adduct, 5% by weight polypro pyleneglycol diglycidyl ether, 2% by weight Ciba Darocure R. 1173, 2% by weight adipic acid, 0.6% by weight succinic acid and 1% by weight inorganic pigment Aluminum paste-100.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 13-15%. The flux was completely tack free when coated and dried instantly. The tack was characterized by IPC-TM-650 method 2.4.44 dated March 1998.

### EXAMPLE 18

A pliable and reflective flux was prepared as described in Example 1 by combining different types of binding resins, KE604, partially dimerized rosins (Poly-Pale), plasticizers, organic acids such as adipic acid. The flux is reflective in nature, pigment carbon black was dispersed in the flux. The flux in this example contains 1.6% by weight binding resins, 0.6% by weight Ke604, 0.4% by weight Polypale rosin, 2.2% by weight adipic acid, 0.6% by weight plasticizers, 1% by weight pigment carbon black. This flux was coated on the ribbons. This yielded black colored coating for aesthetics of the solar panel.

Resiliency of this flux was tested by twisting the flux coated ribbon beyond 360° and bending the ribbon beyond the angle 360° and inspecting for cracks, adhesion of the coating on the ribbon. The flux was completely tack free when coated and dried instantly. The tack was characterized by IPC-TM-650 method 2.4.44 dated March 1998.

### EXAMPLE 19

A pliable and reflective flux was prepared as described in Example 1 by combining different types of binding resins, plasticizers, organic acids such as adipic acid and succinic acids and dispersing agents. The flux is reflective in nature, inorganic pigment like Polygloss 90 and Aluminum paste 100 are dispersed in the flux. The flux in this example contains 5% by weight binding resins, 2.2% by weight adipic acid and succinic acid, 0.6% by weight Disperse-BYK-180, 1.2% by weight pigment polygloss 90 and Aluminum paste. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux was subjected to reflectivity analysis and possess reflectivity of 15-16%. The flux was completely tack free when coated and dried instantly. The tack was characterized by IPC-TM-650 method 2.4.44 dated March 1998.

### EXAMPLE 20

Example 1 was repeated the flux in this example contains equal amount of 2.5% by weight two binding resins, 2.2% by weight organic acids such as adipic and succinic acids, 0.8% by weight plasticizers and 1.1% by weight pigment. This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux coated ribbon was subjected to reflectivity analysis and possess reflectivity of 34-38%, The flux was completely tack free when coated and dried for a 5 to 6 seconds, the tack was characterized by IPC-TM-650 method 2.4.44 dated March 1998.

### EXAMPLE 21

Example 1 was repeated the flux in this example 4% by weight binding resins, 2.2% by weight organic acids such as adipic and succinic acids, 1% by weight plasticizers and 1.1% by weight pigment spacer such as polygloss-90 and BLR-698 (TiO₂ submicron particles). This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux coated ribbon was subjected to reflectivity analysis and possess reflectivity of 33-36%, The flux was completely tack free when coated and dried for a 5 to 6 seconds, the tack was characterized by IPC-TM-650 method 2.4.44 dated March 1998.

### EXAMPLE 22

Example 1 was repeated the flux in this example 3.8% by weight binding resins, 2.2% by weight organic acids such as adipic and succinic acids, 0.8% by weight plasticizers, along with 0.6% Ke604, 0.4% polypal Rosins, and 1.1% by weight pigment spacer polygloss-90 and BLR-698 (TiO₂ submicron particles). This flux was coated on the ribbons and the ribbons were subjected to reflectivity analysis, the high reflectiveness of these fluxes in turn increases the power output of the solar panel by 2.5%.

Resiliency of this flux was tested by twisting the flux coated ribbon beyond 360° and bending the ribbon beyond the angle 360° and inspecting for cracks, adhesion of the coating on the ribbon. The flux coated ribbon was subjected to reflectivity analysis and possess reflectivity of 31-35%, The flux was completely tack free when coated and dried for a 5 to 6 seconds, the tack was characterized by IPC-TM-650 method 2.4.44 dated March 1998.

### EXAMPLE 23

Example 21 was repeated except that carbon black was added in addition to the inorganic white pigment (TiO₂).

### EXAMPLE 24

Example 21 was repeated except that carbon black was added to the composition in lieu of inorganic white pigment (TiO₂) and pigment spacer such as polygloss-90. This is non reflective flux used to improve aesthetics of the solar panel.

### EXAMPLE 25

Example 21 was repeated except that solvent black 27 was added in addition to the inorganic white pigment (TiO₂). This gave black colored coating to the ribbon, ideal for aesthetic purpose and slight improvement in reflectivity.

A summary of the results pf these examples is as follows:

| Example | Reflectivity | Tack |
|---|---|---|
| Example 1 | 34-36% | Non-Tacky |
| Example 2 | 27-30% | Non-Tacky |
| Example 3 | 30-32% | Non-Tacky |
| Example 4 | 33-35% | Non-Tacky |
| Example 5 | 33-36% | Non-Tacky |
| Example 6 | 14-16% | Non-Tacky |
| Example 7 | 35-38% | Non-Tacky |
| Example 8 | 40-50% | Non-Tacky |
| Example 9 | 40-50% | Non-Tacky |
| Example 10 | 40-50% | Non-Tacky |
| Example 11 | 40-50% | Non-Tacky |
| Example 12 | 14-16% | Tacky |
| Example 13 | 14-15% | Non-Tacky |
| Example 14 | 13-16% | Non-Tacky |
| Example 15 | 13-16% | Non-Tacky |
| Example 16 | 14-16% | Non-Tacky |
| Example 17 | 13-15% | Non-Tacky |
| Example 18 | 14-16% | Non-Tacky |
| Example 19 | 15-16% | Non-Tacky |
| Example 20 | 34-38% | Non-Tacky |
| Example 21 | 33-36% | Non-Tacky |
| Example 22 | 31-35% | Non-Tacky |

The foregoing detailed description has been provided by way of explanation and illustration, and is not intended to limit the scope of the appended claims. Many variations in the presently preferred embodiments illustrated herein will be apparent to one of ordinary skill in the art and remain within the scope of the appended claims and their equivalents.

1. A method of manufacturing a solar module, the method comprising:
connecting a metallic interconnector to two or more solar cells; and
applying a transparent cover sheet to the two or more solar cells,
wherein connecting the metallic interconnector to each solar cell of the two or more solar cells comprises:
providing a solar cell having a bus bar on a surface thereof;
providing a metallic interconnector having solder flux on a contact surface thereof;
providing solder between the bus bar and the contact surface; and
reflowing the solder to connect the metallic interconnector to the bus bar,
wherein the solder flux comprises a reflective additive.

2. The method of claim 1, wherein the reflective additive comprises a dye and/or a pigment.

3. The method of claim 1, wherein the reflective additive comprises a pigment comprising one or more of iron oxide, zinc oxide, aluminum oxide, titanium dioxide, chromium oxide, and ferric ammonium ferrocyanide.

4. The method of claim 1, wherein the reflective additive comprises a pigment comprising titanium dioxide, preferably wherein the titanium dioxide is in the form of flakes, more preferably wherein the titanium oxide flakes are coated with alumina and/or zirconia.

5. The method of claim 1, wherein the dye comprises a fluorescent dye.

6. The method of claim 1, wherein the reflective additive is white or yellow, the flux comprises from 0.1 to 15 wt. % reflective additive based on the total weight of the solder flux, preferably from 0.3 to 2 wt. % reflective additive.

7. (canceled)

8. (canceled)

9. The method of claim 1, wherein the solder flux further comprises an acrylic resin binder, preferably a methacrylic resin binder.

10. The method of claim 9, wherein the solder flux comprises from 1 to 10 wt. % acrylic resin binder based on the total weight of the solder flux, preferably from 2 to 6 wt. % acrylic resin binder.

11. The method of claim 1, wherein the solder flux further comprises a vinyl resin binder.

12. The method of claim 11, wherein the solder flux comprises from 0.1 to 5 wt. % vinyl resin binder based on the total weight of the solder flux, preferably from 0.5 to 2 wt. % vinyl resin binder.

13. The method of claim 1, wherein the solder flux comprises an acrylic resin binder and a vinyl resin binder.

14. The method of claim 1, wherein the solder flux further comprises an activator, preferably an activator comprising a dicarboxylic acid, preferably wherein the dicarboxylic acid is selected from one or more of adipic acid, glutaric acid and succinic acid.

15. The method of claim 14, wherein the solder flux comprises from 1 to 5 wt. % activator based on the total weight of the solder flux.

16. The method of claim 1, wherein the solder flux further comprises one or more of a resin, a rosin, a wetting agent, an antifoaming agent, a plasticiser, and a dispersing agent.

17. The method of claim 1, wherein the bus bar comprises a copper, tin or silver connection pad, and wherein reflowing the solder connects the metallic interconnector to the copper, tin or silver connection pad.

18. The method of claim 1, wherein the metallic interconnector comprises a copper or copper alloy ribbon.

19. The method of claim 1, wherein the transparent cover sheet comprises glass, preferably textured glass.

20. A method of connecting a metallic interconnector to a solar cell, the method comprising:
providing a solar cell having a bus bar on a surface thereof;
providing a metallic interconnector having solder flux on a contact surface thereof;
providing solder between the bus bar and the contact surface, and
reflowing the solder to connect the metallic interconnector to the bus bar,
wherein the solder flux comprises a reflective additive.

21. A metallic interconnector for a solar cell, the metallic interconnector having solder flux on a surface thereof, the solder flux comprising a reflective additive and being substantially free of solvent.

22. (canceled)

23. (canceled)

24. (canceled)

25. (canceled)

26. (canceled)

27. (canceled)

28. (canceled)

29. (canceled)

30. (canceled)

31. A solar module manufactured according to the method of claim 1.

32. (canceled)

33. (canceled)
